(19) United States
(12) Patent Application Publication
(10) Pub. No.: US 2009/0117686 A1
(43) Pub. Date: May 7, 2009

(54) METHOD OF FABRICATING ORGANIC SEMICONDUCTOR DEVICE

(75) Inventors: Liang-Ying Huang, Hsinchu City (TW); Tsung-Hsien Lin, Hsinchu City (TW); Hsiang-Yuan Cheng, Taipei City (TW); Tarng-Shiang Hu, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/350,931

(22) Filed: Jan. 8, 2009

Related U.S. Application Data
(62) Division of application No. 11/564,301, filed on Nov. 29, 2006.

(30) Foreign Application Priority Data
Jul. 31, 2006 (TW) 95127931

(51) Int. Cl. H01L 51/30

(52) U.S. Cl. 438/99; 257/E51.027

(57) ABSTRACT

A method of fabricating an organic semiconductor device includes following steps. A gate conductive layer is formed on a substrate, and then a gate dielectric layer is formed. Next, patterned metal layers are formed on the gate dielectric layer beside the gate conductive layer. An electrode modified layer is then formed on the surface and the sidewall of each patterned metal layer, and the patterned metal layers and the electrode modified layers formed thereon serve as a source and a drain. Thereafter, an organic semiconductor layer is formed on the source and the drain and on a portion of the gate dielectric layer exposed between the source and the drain to be an active layer.

### CROSS-REFERENCE TO RELATED APPLICATION

This application is a divisional application of, and claims the priority benefit of, U.S. application Ser. No. 11/564,301 filed on Nov. 29, 2006, which claims the priority benefit of Taiwan application serial No. 95127931, filed on Jul. 31, 2006. The entirety of the above-mentioned provisional application is hereby incorporated by reference herein and made a part of this specification.

### BACKGROUND OF THE INVENTION

1. Field of the Invention

The present invention relates to an integrated circuit and a method of fabricating the same, and more particularly, to an organic semiconductor device and a method of fabricating the same.

2. Description of Related Art

An organic thin film transistor (OTFT) is fabricated by the material comprising organic conjugate polymer or oligomer. Compared with the traditional inorganic transistor, the OTFT can be fabricated under a relative low temperature, thus the lighter, thinner, and cheaper plastic can be used as the material of the substrate to replace glass. In addition, the fabricating process of an OTFT is comparatively simple and has development potential.

Though OTFT has the above described advantages, some drawbacks such as slow carrier mobility and high driving voltage are needed to be solved. The main reason that the carrier mobility is very slow is: the grain size of the organic semiconductor of the active layer is varied along with the material property and the surface roughness of the underneath layer; boundaries exist between small grains, and these boundaries hinder the transition of the carriers. Thus, the carrier mobility is slowed down, and electrical characteristics of devices are affected, thereby restricting the development and applications of the OTFT.

Currently, major researches are focused on how to have the organic semiconductor of the active layer exist in the form of single crystal or grain having larger size. One of the remarkable methods is to modify the property of the surface where the organic semiconductor is deposited; that is, the dielectric layer is covered by a middle layer which is capable of improving the crystal phase of the organic semiconductor. However, the grains formed on the surface and the boundaries of the metal electrodes are still small. Therefore, some researches involving forming a single layer of self-align material (SAM) on the surface of the metal layer or modifying the semiconductor material to help the semiconductor grain arrangement are developed. However, the single layer of self-align material has disadvantages of easily vaporizing and unstable quality. The method of modifying the semiconductor material has a drawback of affecting the semiconductor material property.

### SUMMARY OF THE INVENTION

The present invention is directed to an organic semiconductor device and a method for fabricating the same having higher carrier mobility to reduce power consuming.

The present invention is also directed to an organic semiconductor device and a method for fabricating the same which can change the arrangement of the organic semiconductor grains on the surface and the boundaries of the metal electrode and increase the grain size.

The present invention provides a method of fabricating an organic semiconductor device. A gate conductive layer is formed on a substrate, and then a gate dielectric layer is formed. Next, patterned metal layers are formed on the gate dielectric layer beside the gate conductive layer. Then, an electrode modified layer is formed on the surface and the sidewall of each patterned metal layer, and the patterned metal layers and the electrode modified layers formed thereon serve as a source and a drain. Thereafter, an organic semiconductor layer is formed on the source and the drain and on a portion of the gate dielectric layer exposed between the source and the drain to be an active layer.

The present invention provides an organic semiconductor device comprising a gate conductive layer, a gate dielectric layer, a source and a drain, and an active layer. The gate conductive layer is disposed on the substrate. The gate dielectric layer covers the substrate and the gate conductive layer. The source and the drain are disposed on the gate dielectric layer beside the gate conductive layer, and the source and the drain are formed of the patterned metal layers and the electrode modified layers covering on the surface and the sidewall of the patterned metal layers. The active layer covers a portion of the source and the drain and fills a gap between the source and the drain.

The present invention provides an organic semiconductor device comprising two electrodes and an organic semiconductor layer. Each electrode includes a patterned metal layer and an electrode modified layer covering on the surface and the sidewall of the patterned metal layer. The organic semiconductor layer is disposed between the two electrodes and extends to cover a portion of the electrode modified layers.

In the present invention, an organic conductive layer is added between the metal electrode and the organic semiconductor active layer, thereby the grains of the organic semiconductor active layer on the metal electrode become larger, such that the carrier mobility of the device can be improved.

The electrode is formed of the organic conductive layer and the metal layer, and therefore its work function can match the semiconductor material more, and it also can compensate the insufficient conductivity problem when only the conductive polymer is used as the material of the electrode.

The method for forming the organic conductive layer can be coating a conductive polymer electrode material with a fully coating process and then patterning the conductive polymer electrode material by laser, thereby its surface is more planar compared with that of layers formed with inkjet printing or screen printing.

Various specific embodiments of the present invention are disclosed below, illustrating examples of various possible implementations of the concepts of the present invention. The following description is made for the purpose of illustrating the general principles of the invention and should not be taken in a limiting sense. The scope of the invention is best determined by reference to the appended claims.

### BRIEF DESCRIPTION OF THE DRAWINGS

FIGS. 1A to 1D are cross-sectional views illustrating a method for fabricating an organic semiconductor device according to an embodiment of the present invention.

FIGS. 2A to 2C are cross-sectional views illustrating a method for fabricating an organic semiconductor device according to another embodiment of the present invention.

### DESCRIPTION OF EMBODIMENTS

In the present invention, an organic conductive layer is added between the metal electrode and the organic semiconductor active layer, and it has a work function matching with the semiconductor material. In addition, the present invention can also help the arrangement of the organic semiconductor grains and make the grains of the organic semiconductor active layer on the metal electrode become larger, so as to improve the carrier mobility of the device. The present invention can be applied to the organic semiconductor devices, and is described as follows.

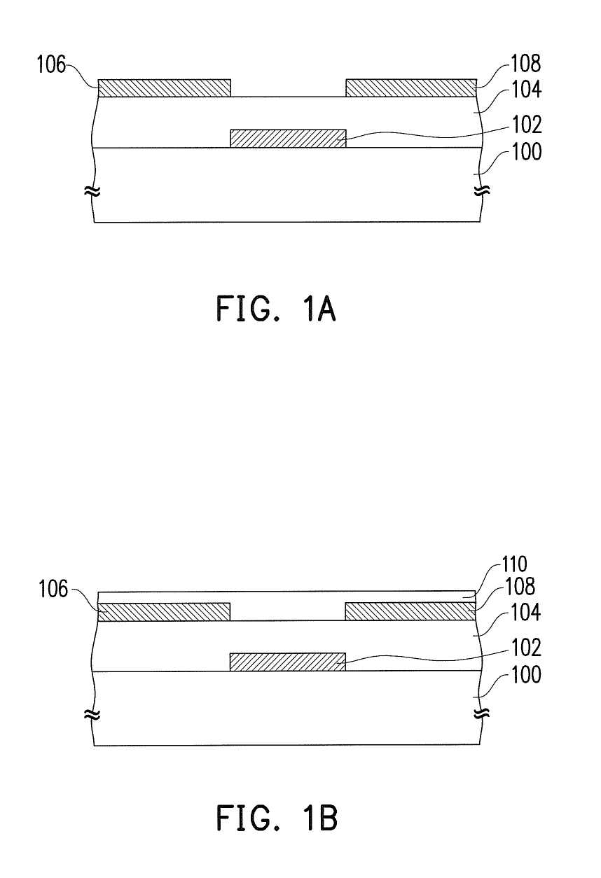

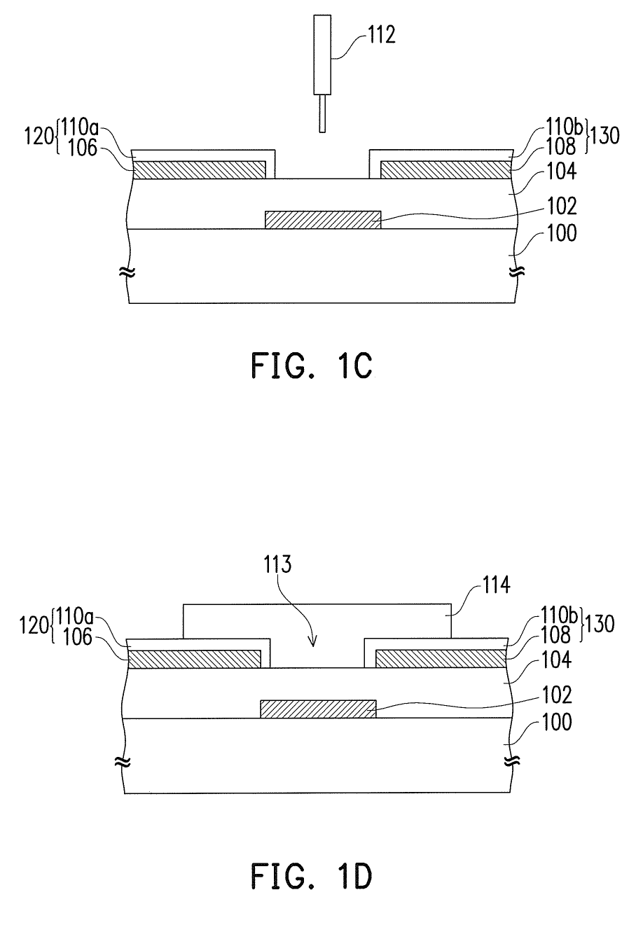

FIGS. 1A to 1D are cross-sectional views illustrating a method for fabricating an organic semiconductor device according to an embodiment of the present invention.

Please refer to FIG. 1A, a gate conductive layer 102 is formed on a substrate 100. The substrate 100 can be a flexible substrate or a rigid substrate, wherein the material of the flexible substrate is plastic, for example, and the material of the rigid substrate is silicon, glass or quartz, for example. The gate conductive layer 102 is formed by forming a conductive layer, such as a polysilicon layer or a metal layer, on the substrate 100, and then patterning the conductive layer by a photolithography and etching process.

Next, a gate dielectric layer 104 is formed over the substrate 100, and the material of the gate dielectric layer 104 is an inorganic material or a polymer material having a dielectric constant larger than 3, or a high dielectric constant material having a higher dielectric constant. The gate dielectric layer 104 can be formed by spin coating or spin-slide coating.

Thereafter, metal layers 106 and 108 are formed on the gate dielectric layer 104. The metal layers 106, 108 can be formed of a single metal material, such as gold or silver, or an alloy composed of two or more metal materials, such as Ti—Al—Ti. The metal layers 106 and 108 can be formed by depositing process with a shallow mask.

Next, please refer to FIG. 1B, an electrode modified material layer 110 is formed over the substrate 100. The material of the electrode modified material layer 110 is, for example, a conductive polymer material, such as poly(3,4-ethylenedioxythiophene), poly(styrenesulfonate)(PEDOT:PSS), polyaniline or polypyrrole, and its thickness is, for example, from 500 angstrom to 1500 angstrom. The electrode modified material layer 110 can be coated on the metal electrodes 106, 108 and on the gate dielectric layer 104 between the metal electrodes 106, 108 by spin coating.

Then, please refer to FIG. 1C, the electrode modified material layer 110 is patterned to form electrode modified layers 110a and 110b covering the top surface and the sidewall of the metal layers 106, 108, such that the electrode modified layer 110a and the metal electrode 106 form a source 120, and the electrode modified layer 110b and the metal electrode 108 form a drain 130. The electrode modified material layer 110 is patterned by, for example, laser 112, screen printing or inkjet printing, to remove a portion of the electrode modified material layer 110 positioned between the metal layers 106 and 108 and remain the electrode modified layers 110a, 110b on the top surface and the sidewall of the metal electrodes 106, 108.

Please refer to FIG. 1D, an active layer 114 is formed over the substrate 100 to cover a portion of the source 120 and the drain 130 and fill the gap 113 between the source 120 and the drain 130. The material of the active layer 114 is, for example, an organic semiconductor material, such as pentacene or poly(3-hexylthiophene) (P3HT). The active layer 114 is formed by, for example, thermal evaporation or solution process which is a coating process, such as a spin coating process, to form a film layer, and then patterning the film layer by photolithography and etching process. In addition, the active layer 114 can also be formed with a direct deposition patterning process, such as an inkjet printing process, a contact printing process or the like.

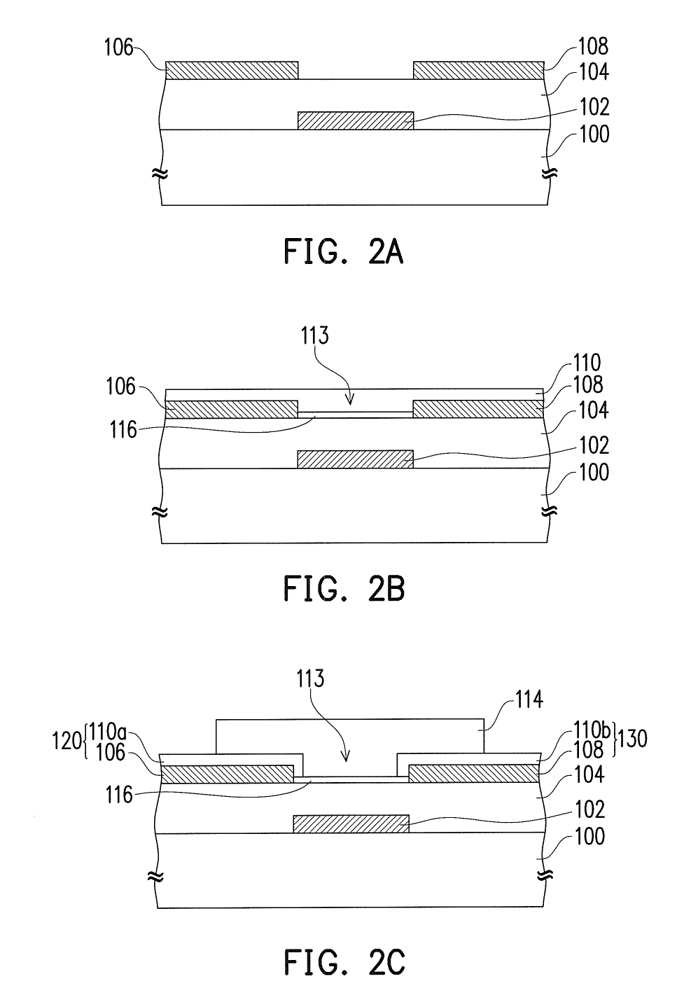

FIGS. 2A to 2C are cross-sectional views illustrating a method for fabricating an organic semiconductor device according to another embodiment of the present invention.

Please refer to FIG. 2A, in another embodiment, a gate conductive layer 102, a gate dielectric layer 104 and metal layers 106, 108 are formed over the substrate 100 according to the method described in the foregoing embodiment.

Please refer to FIG. 2B, before forming the electrode modified material layer 110, a middle layer 116 is formed on the gate dielectric layer 104 between the metal layers 106, 108. The material of the middle layer 116 is, for example, octadecyltrichlorosilane (OTS) monolayer, polyimide or polymethyl methacrylate, and its thickness is between 500 angstrom and 1500 angstrom. The middle layer 116 is formed, by forming a film layer with a spin coating process, and then patterning the film layer with a photolithography and etching process. In addition, the middle layer 116 can also be formed with a direct deposition patterning process, such as an inkjet printing process, a contact printing process or the like. The middle layer 116 would change the arrangement of the organic semiconductor grains of the active layer subsequently formed covering the gate dielectric layer 104. After forming the middle layer 116, an electrode modified material layer 110 is formed with the method described above.

After that, please refer to FIG. 2C, the electrode modified material layer 110 is patterned with the method described above to form an electrode modified layer 110a and an electrode modified layer 110b, wherein the electrode modified layer 110a and the metal electrode 106 form a source 120 and the electrode modified layer 110b and the metal electrode 108 form a drain 130. Next, an active layer 114 is formed with the method described above.

Generally, the grain size of the organic semiconductor on the silicon oxide layer is about 0.2-0.5 μm, however, it would be reduced significantly if the organic semiconductor is formed on the metal electrode, such as Au, such that the electron mobility of the bottom contact device is about equal or less than 0.16 cm2V-1s⁻¹. In the present invention, an organic conductive layer is added between the metal layer and the organic semiconductor layer, such that the grains of the organic semiconductor of the active layer become larger, and the work function of the organic conductive layer matches with that of the semiconductor material. Hence, the electron mobility can achieve about 0.48 cm2V-1s⁻¹ or more. That is, the electron mobility can be increased by 3 times. In addition, the conductive polymer material used as the electrode modified layer can be formed by coating a film layer on the metal electrode by spin coating or printing, and then patterning the film layer with laser, and therefore the formed electrode modified layer has a planar surface. In addition, the method for forming the electrode modified layer is simple and the electrode modified layer does not have the disadvantages of easily vaporizing and unstable quality.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A method of fabricating an organic semiconductor device, comprising:
forming a gate conductive layer on a substrate;
forming a gate dielectric layer over the substrate and the gate conductive layer;
forming patterned metal layers on the gate dielectric layer beside the gate conductive layer;
forming an electrode modified layer on the top surface and the sidewall of each patterned metal layer, the patterned metal layers and the electrode modified layers formed thereon being as a source and a drain; and
forming an organic semiconductor layer on the source and the drain and on a portion of the gate dielectric layer exposed between the source and the drain to be an active layer.

2. The method of fabricating an organic semiconductor device as claimed in claim 1, wherein the method for forming the electrode modified layers comprises:
forming an electrode modified material layer over the substrate to cover the patterned metal layers and the gate dielectric layer; and
removing a portion of the electrode modified material layer between the patterned metal layers by laser irradiation.

3. The method of fabricating an organic semiconductor device as claimed in claim 2, wherein the method for forming the electrode modified material layer comprises a spin coating process.

4. The method of fabricating an organic semiconductor device as claimed in claim 1, wherein the material of the electrode modified layer comprises a conductive polymer material.

5. The method of fabricating an organic semiconductor device as claimed in claim 4, wherein the conductive polymer material comprises poly(3,4-ethylenedioxythiophene), poly(styrenesulfonate)(PEDOT:PSS), polyaniline or polypyrrole.

6. The method of fabricating an organic semiconductor device as claimed in claim 1, wherein the material of the organic semiconductor layer comprises pentacene or poly(3-hexylthiophene)(P3HT).

7. The method of fabricating an organic semiconductor device as claimed in claim 1, further comprising forming a middle layer on the exposed gate dielectric between the two patterned metal layers between the steps of forming the patterned metal layers and forming the electrode modified layers.

8. The method of fabricating an organic semiconductor device as claimed in claim 7, wherein the material of the middle layer comprises octadecyltrichlorosilane monolayer, polyimide or polymethyl methacrylate.
